(19) United States
(12) Patent Application Publication
(10) Pub. No.: US 2007/0054064 A1
(43) Pub. Date: Mar. 8, 2007

(54) Microwave plasma processing method, microwave plasma processing apparatus, and its plasma head

(76) Inventors: Tadahiro Ohmi, Sendai (JP); Masaki Hirayama, Sendai (JP); Takahiro Horiguchi, Tsukui (JP); Akihiko Hiroe, Tsukui (JP); Masayuki Kitamura, Tsukui (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 10/566,241

(22) PCT Filed: Dec. 24, 2004
(86) PCT No.: PCT/JP04/19772

§ 371 Date: Oct. 4, 2006

(30) Foreign Application Priority Data
Dec. 26, 2003 (JP) 2003-431939

(51) Int. Cl. H05H 1/24; C23C 16/00

(52) U.S. Cl. 427/569; 118/723 MW; 118/719

(57) ABSTRACT

A microwave plasma processing method and, in which a linear plasma is produced by means of a microwave, and an object to be processed is subjected to processing under atmospheric pressure or under a pressure near atmospheric pressure when the object is moved, while a surface of the object is maintained at a horizontal position with respect to the linear plasma. A plasma head has an H-plane slot antenna, and slots are arranged alternately on both sides of a centerline of a waveguide at a pitch of λg/2 (λg: wavelength of the microwave with the waveguide). A uniforming line having a distance of n·λg/2 from the slots to an emission end of the plasma head is provided (n: an integral number).

### FIELD OF THE INVENTION

The present invention relates to a microwave plasma processing method, a microwave processing apparatus and its plasma-head, used for the microwave plasma processing of a large type glass substrate for flat panel display (FPD) or a substrate such as a semiconductor wafer.

### BACKGROUND ART

For instance, in a microwave plasma CVD processing apparatus for processing a large type glass substrate for FPD or a substrate such as a semiconductor wafer, it has been practiced in the past in such manner that a batch processing of the sheet-by-sheet type has been carried out and the substrates to be processed by plasma CVD processing has been passed through a load-lock chamber kept under vacuum condition and the substrates have been brought into or out of a processing chamber maintained similarly under a predetermined vacuum condition. As a result, each time the substrates were brought into or out of the processing chamber, the processing chamber had to be evacuated and released to atmosphere.

In particular, when two or more different processing procedures had to be applied on the substrates, each of such processing procedures had to be performed in batch processing procedure with the substrates being transferred through a plurality of isolated spaces (i.e. the processing chamber). For this reason, it was not possible to continuously carry out the CVD processing of the substrates, and expensive vacuum processing means had to be used.

Under such circumstances, a new technique has been developed, in which no such vacuum processing means is required and plasma CVD processing is continuously carried out on in-line basis under the atmospheric pressure (normal pressure). In the new plasma CVD technique under normal pressure, a plasma technique is used, which makes it possible to operate under the atmospheric pressure without using vacuum system, and the substrate to be processed such as a semiconductor wafer is continuously subjected to CVD, etching and ashing processing (Non-Patent Reference 1). Further, in this normal pressure plasma CVD technique, semiconductor wafers are placed on a circulating type wafer transfer unit such as a belt conveyer and different types of processing are carried out on flow production (flow shop) system by using a plurality of normal pressure plasma systems (Non-Patent Reference 2).

Also, a new plasma processing apparatus (e.g. CVD apparatus) has been proposed (Patented Reference 1), in which a linear plasma is prepared by using electromagnetic wave, and surface treatment of the object to be processed is performed while relative position between the object to be processed (such as semiconductor wafer) and the plasma is being moved with the surface of the object to be processed maintained at horizontal position with respect to the linear plasma.
[Non-Patented Reference 1] Motokazu YUASA “Plasma CVD Technique Without Using Vacuum Technique”, Nikkei Microdevices, January 2001, p. 3.
[Non-Patented Reference 2] Motokazu YUASA “Plasma Technique Without Using Vacuum Technique”, Nikkei Microdevices, April 2001; pp. 139-146.
[Patented Reference 1] JP-A-2001-93871.

### DISCLOSURE OF THE INVENTION

Although different types of processing can be continuously carried out by the conventional type microwave plasma CVD method and apparatus as described above, there have been problems in: non-uniformity of microwave at the microwave feeding unit of the plasma head, incompleteness of processing of gas flow and gas shielding, non-uniformity of plasma density due to the standing wave, abnormal discharge at slots of the plasma head, etc.

To solve the problems of the conventional type microwave plasma CVD processing method and processing apparatus as described above, it is an object of the present invention to provide microwave plasma processing method, a microwave plasma processing apparatus, and a plasma head for such apparatus, by which it is possible to generate linear high-density plasma by using high-density microwave source, and different types of film-deposition processing can be continuously performed.

According to the microwave plasma processing method, the microwave plasma processing apparatus and the plasma head of the present invention, linear plasma is generated by microwave, and an object to be processed is processed under the atmospheric pressure or under a pressure near the atmospheric pressure while the object to be processed is being moved by maintaining the surface of the object to be processed at horizontal position with respect to the linear plasma. An H-plane slot antenna is provided on the plasma head. Slots of the H-plane slot antenna are arranged alternately on both sides of the centerline of the waveguide at a pitch of λ g/2, and a uniforming line is arranged with a distance from said slot to the emission end of the plasma head being set to n·λg/2 where the symbol λg represents guide wavelength of microwave.

Also, according to the microwave plasma processing method, the microwave plasma processing apparatus and the plasma head of the present invention, linear plasma is generated by microwave, and an object to be processed is processed under the atmospheric pressure or under a pressure near the atmospheric pressure while the object to be processed is being moved by maintaining the surface of the object to be processed at horizontal position with respect to the linear plasma. An E-plane slot antenna is provided on the plasma head. Slots of the E-plane slot antenna are arranged along the centerline of the waveguide at a pitch of λg, and a uniforming line is arranged with a distance from said slot to the emission end of the plasma head being set to n·λg/2 where the symbol λg represents guide wavelength of microwave.

Further, according to the microwave plasma processing method, the microwave plasma processing apparatus and the plasma head of the present invention, a uniforming line is provided on the plasma head under similar processing conditions, and the uniforming line is made of a material with high dielectric constant. Also, the uniforming line is made of quartz, and its end portion is extended by ¼ λ. Also, an electromagnetic wave absorbing material with high dielectric loss is attached on end portion of the uniforming line to reduce the standing wave on the plasma head where the symbol λ represents free space wavelength of quartz.

Also, according to the microwave plasma processing method, the microwave plasma processing apparatus and the plasma head of the present invention, it is designed in such manner that a film-deposition gas is passed by down-flowing through a film-deposition gas feeding nozzle provided on the plasma head under similar processing conditions, and also, that a film-deposition gas is passed by side-flowing through the film-deposition gas feeding nozzle.

Further, according to the microwave plasma processing method, the microwave plasma processing apparatus and the plasma head of the present invention, a feeding pipe for feeding a shield gas into the plasma head is connected, and by a buffer plate the shield gas is uniformly supplied into the plasma processing chamber downstream of the shield gas feeding pipe. Also, a buffer plate for carrying out uniform exhaust of the gas is provided on exhaust side. A pressure P₁ in the plasma processing chamber is set to a value lower than a pressure P₃ on the outermost periphery of the plasma head, and the pressure P₃ is set to a value lower than a pressure P₂ near the buffer plate for performing uniform exhaust, thus preventing the leakage of the gas from the plasma head.

According to the microwave plasma processing method, the microwave plasma processing apparatus and the plasma head of the present invention, linear high-density plasma is generated from the plasma head by using a high-density microwave source. As a result, it is possible to perform continuous CVD processing with high accuracy. Different types of plasma sources are aligned in transporting direction of the substrate to be processed by film-deposition processing. As a result, different types of continuous film deposition can be carried out.

Further, according to the microwave plasma processing method, the microwave plasma processing apparatus and the plasma head, and a uniforming line of the plasma head of the present invention, by setting optimal condition of the basic dimensions and by eliminating the standing wave, more uniform microwave can be emitted through the slit of the plasma head. Also, homogeneity of the film deposition gas can be maintained because of down-flowing and side-flowing of the gas, and this contributes to the improvement of the film deposition rate.

Also, remarkable effects can be provided for gas shielding of the film deposition gas with very high accuracy.

### BRIEF DESCRIPTION OF THE DRAWINGS

FIG. 1 is a front view to show schematical arrangement of a microwave plasma CVD apparatus according to an embodiment of the present invention;

FIG. 2 is a plan view of the microwave plasma CVD apparatus shown in FIG. 1;

FIG. 3 is a perspective view of three plasma heads to be used in the microwave plasma CVD apparatus shown in FIG. 1 with the plasma heads aligned in parallel and in clustering;

FIG. 4 is a perspective view of a microwave feeding unit of the plasma head shown in FIG. 3;

FIG. 5 represents schematical drawings of the microwave feeding unit of FIG. 4;

FIG. 6 represents a perspective view of an antenna to be used in the microwave feeding unit shown in FIG. 4 and a diagram to show propagation of microwave within the antenna;

FIG. 7 represents a perspective view of an E-plane antenna of in-phase emission type and a diagram to show propagation of microwave within the E-plane antenna;

FIG. 8 is a plan view showing dimensions of a slot plate of an H-plane antenna of in-phase emission type shown in FIG. 6;

FIG. 9 is a schematical drawing to show a procedure to calculate basic dimensions of the microwave feeding unit of the plasma head to be used in the microwave plasma CVD apparatus in an embodiment of the present invention;

FIG. 10 is a schematical drawing to show another procedure to calculate basic dimensions of a uniforming line of the microwave feeding unit of the plasma head to be used in the microwave plasma CVD apparatus in an embodiment of the present invention;

FIG. 11 represents drawings to show means for reducing the standing wave at the microwave feeding unit of the plasma head (longitudinal sectional view) to be used in the microwave plasma CVD apparatus shown in FIG. 1;

FIG. 12 is a drawing to show how to flow CVD gas at the plasma head of the microwave plasma CVD apparatus shown in FIG. 1 when CVD gas is passed by down-flowing in a plasma processing chamber;

FIG. 13 is a drawing to show the plasma head (longitudinal sectional view) of the microwave plasma CVD apparatus of FIG. 1 when CVD gas is passed by side-flowing in the plasma processing chamber; and

FIG. 14 represents a drawing and a diagram to show the plasma head of the microwave plasma CVD apparatus of FIG. 1, showing how to provide gas shielding.

### BEST MODE FOR CARRYING OUT THE INVENTION

Detailed description will be given below on embodiments of a microwave plasma processing method, a microwave plasma processing apparatus and a plasma head according to the present invention referring to the attached drawings.

[Microwave Plasma CVD Apparatus]

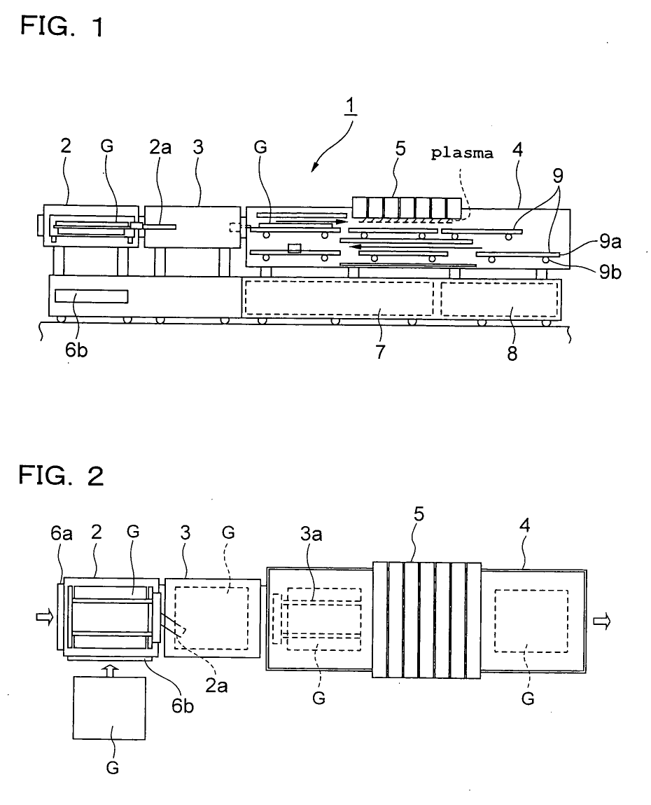

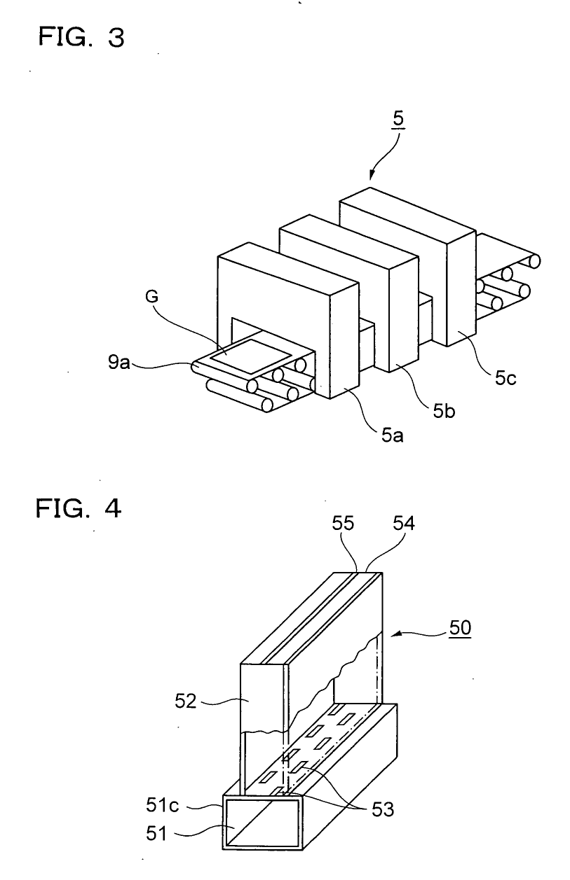

First, as shown in FIG. 1 and FIG. 2, in a microwave plasma CVD apparatus 1 in an embodiment of the present invention (hereinafter referred as “CVD apparatus of the present invention”), a substrate G (e.g. a glass substrate) is brought into a load-lock module 2 from a platform 6a or 6b and is sent to a process module 4 by a robot arm 3a via a transfer module 3 by a transport arm 2a. Then, linear plasma of high density is generated by a plasma head 5. Under the presence of the linear plasma, processing surface of the substrate (object to be processed) G is maintained at horizontal position with respect to the linear plasma, and plasma CVD processing is continuously performed on in-line basis on the substrate G. In particular, the plasma head 5 comprises one or several plasma heads of the same type arranged in parallel and/or in clustering so that a plurality of different film-deposition processes can be carried out as to be described later (FIG. 3).

Here, the substrate G is transported by the robot arm 3a from the transfer module 3. It is then guided in the process module 4 by a guide rolls 9b and is placed on a substrate stage 9a arranged in a circulating endless substrate transport mechanism 9. Then, it is fixed by means such as an electrostatic chuck (not shown) and is moved in the process module 4, and CVD processing is performed by the plasma heads 5. After CVD processing, the substrate G is separated from the substrate stage 9a and is moved from the end of the process module 4 to the next processing stage. The emptied substrate stage 9a is brought back to the starting end of the process module 4 by the endless substrate transport mechanism 9. Under the endless substrate transport mechanism 9, a gas unit 7 and a cooling water unit 8 are provided.

[Plasma Heads]

Plasma heads to be used in the microwave plasma CVD apparatus in the embodiment of the present invention comprise a plurality of unit plasma heads. For instance, three units 5a, 5b, and 5c are arranged in parallel via partition walls (not shown) as shown in FIG. 3. Different types of processing are carried out by different types of film-deposition gases on the substrate G placed on the substrate stage 9a under the atmospheric pressure (normal pressure) or a pressure near the 5 atmospheric pressure. For instance, as shown in Table 1, film-deposition process by a gas for depositing Si₃N₄ film is performed at the plasma head 5a. A film-deposition process by a gas for depositing a-Si film is performed at the plasma head 5b, and a film-forming process by a gas for forming n⁺Si film is performed at the plasma head 5c. As a result, three different types of film layers are formed on the surface of the substrate G.

To the plasma heads 5, the microwave feeding unit 50 as shown in FIG. 4 is applied.

TABLE 1

| | Process | | |
|---|---|---|---|
| Film gas | gas | Cleaning gas | Carrier gas |
| n⁺Si process | SiH₄PH₃ | NF₃ | Ar or He |
| a-Si process | SiH₄NH₂ | NF₃ | Ar or He |
| Si₃N₄ process | H₂ | | |
| Bank material water repellent | F₂, O₂ | NF₃ | Ar |
| processing | | | |
| Direct Oxidation | | | |
| Stage cleaning | — | NF₃ | Ar |

The microwave feeding unit 50 as shown in FIG. 4 is incorporated in the plasma head 5, and it fulfills the functions as microwave-excited atmospheric pressure linear plasma generating unit. (In FIG. 4, it is shown upside down to more clearly indicate the structure.)

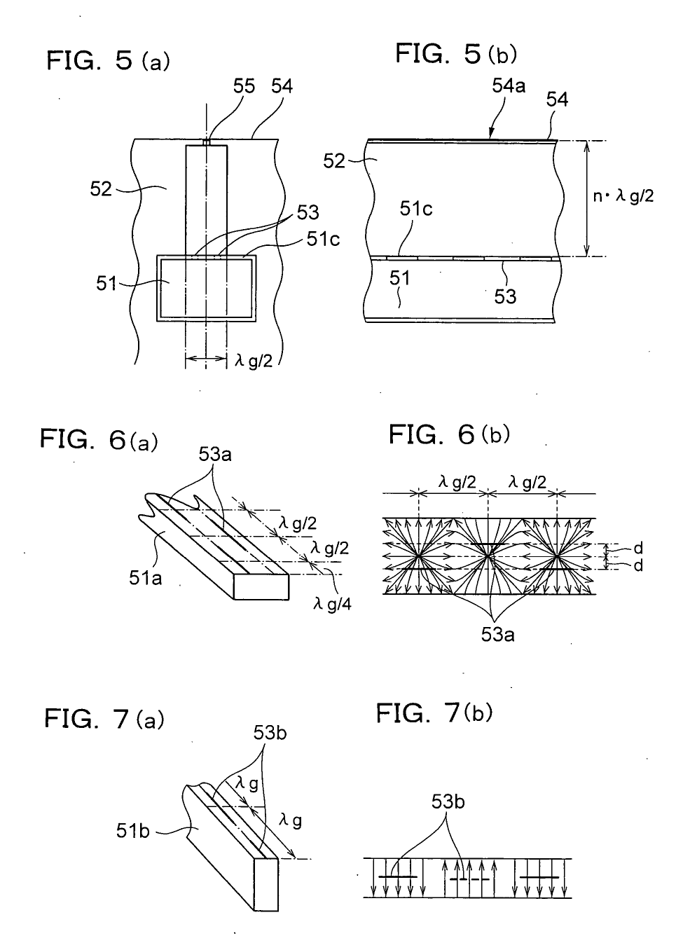

As shown in FIG. 5, the microwave feeding unit 50 is used to form linear plasma by using microwave. It comprises a waveguide 51 serving as an H-plane slot antenna or an E-plane slot antenna and a uniforming line 52. Between the waveguide 51 and the uniforming line 52, a slot array (slot plate) 51c is provided, which comprises a plurality of slots 53. The slot plate 51c comprises, as shown in FIG. 6, a plurality of slots 53 arranged alternately to left and right from the centerline of the waveguide 51 at a pitch of ½ of the guide wavelength λg in case of H-plane antenna. A slit 55 is formed at a microwave emission end 54, which is the end of the uniforming line 52, and the unified microwave is emitted from the slit 55.

On the uniforming line 52, spatially more unified wave front of microwave is formed by using microwave with equal phase as emitted from the slot plate 51. This uniforming line 52 is a parallel flat line. More concretely, it is a flat rectangular waveguide with the centerline as the longer axis. By this uniforming line 52, microwaves discretely emitted from each of the slots 53 are unified. A wave front with more uniform intensity is prepared to the direction of the centerline, and the unified microwaves are emitted into plasma through the slit 55.

In particular, as shown in FIG. 5(a) and FIG. 5(b), the uniforming line comprises H-plane or E-plane antenna of the microwave feeding unit 50 used in the CVD apparatus of the present invention. The dimension from the slot plate 51c of the uniforming line 52 to the emission line 54 of the microwaves is designed as n·λg/2 (where λg is guide wavelength, and n is an integral number), and the width is calculated as λg/2. The uniforming line 52 is made of dielectric substance such as Al₂O₃ or AlN or quartz or a gas (a gas to make up a gaseous space). At the emission line 54 of the microwaves, a fluoride protective film 54a is coated. The waveguide 51 is made of a dielectric substance such as Al₂O₃ or AlN or quartz or a gas (gaseous space).

As shown in FIG. 6(b), on the H-plane antenna of in-phase emission type, an in-phase electric current flows from the centerline at a pitch of λg/2 as shown in the figure. At the centerline, electric field is turned to nearly zero. Thus, at points with relatively high electric field (offset from the centerline by a distance “d”), slots 53a are formed alternately on both sides of the centerline on the waveguide 51a as shown in FIG. 6(a). In this case, a distance from the final end of the waveguide 51a to the middle point of the slot 53a at the end is set to λg/2.

In case of the E-plane antenna, the slots 53 are formed on a waveguide resonator 51b with a spacing of λg along the centerline as shown in FIG. 7(a) and FIG. 7 (b).

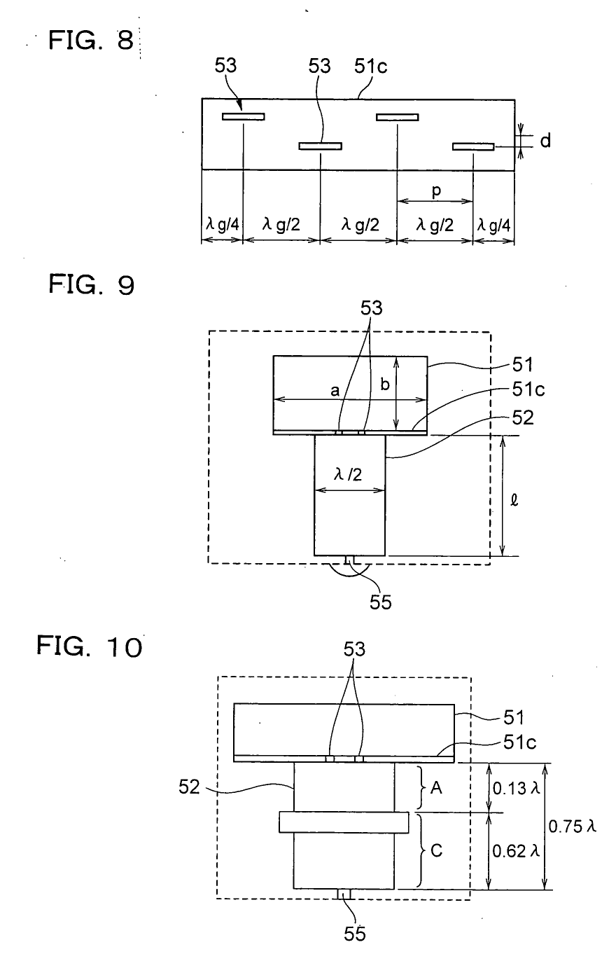

FIG. 8 is a plan view of the slot plate 51c of the H-plane antenna with the above arrangement.

Description will be given on another example of calculation to calculate basic dimensions of the uniforming line 52. As shown in FIG. 9,

$$λ g = \frac{λ}{\sqrt{1 - {( \frac{λ}{{λ}_{C}} )}^{2 }}} \qquad ( Formula 1 )$$

where
λ: Free space wavelength
λc: Cut-off wavelength
λg: Guide wavelength
λc: 2a
a: Width of waveguide
b: Height of waveguide

The length 1 of the uniforming line 52 is basically set to the range of λ/4 to ¾λ. The value is determined by simulation. In this calculating procedure, calculation is made by using free space wavelength λ, and not using the guide wavelength λg. Similarly, calculation is made by setting the width of the uniforming line 52 as λ/2.

Further, as shown in FIG. 10, in case of the unified slit 52, which comprises quartz C on the slit 55 side and with atmospheric air A interposed between the slot 53 and the quartz C, the free space wavelength λ (quartz) in the atmospheric air is determined as follows:

$$λ ( quartz ) = \frac{λ ( atmospheric air )}{\sqrt{} ɛ } \qquad ( Formula 2 )$$

where
λ: Free space wavelength
ε: Dielectric constant

By applying calculation ratio of each component as shown in FIG. 10, wavelength after wavelength reduction in case of quartz (ε=3.58) is calculated. The results are as shown in Table 2.

TABLE 2

| | Dielectric | | | | |
|---|---|---|---|---|---|
| | constant ε | Wavelength λ | 0.75 λ | 0.13 λ | 0.62 λ |
| Atmospheric | 1 | 122.4 mm | 91.8 mm | 16 mm | — |
| air | | | | | |
| Quartz | 3.58 | 64.7 mm | 48.5 mm | — | 40 mm |

Further, in order to eliminate the difference in intensity distribution of the microwaves at the plasma head due to the standing wave, a procedure for reducing the standing wave is applied on the uniforming line 52.

In this procedure to reduce the standing wave, the space of the uniforming line 52 is filled with a material such as alumina (Al₂O₃) with high dielectric constant to shorten the wavelength. In this case, the length 1 of the uniforming line 52 is turned to: λ (free space wavelength) multiplied by an integral number, i.e. 1=n·λ.

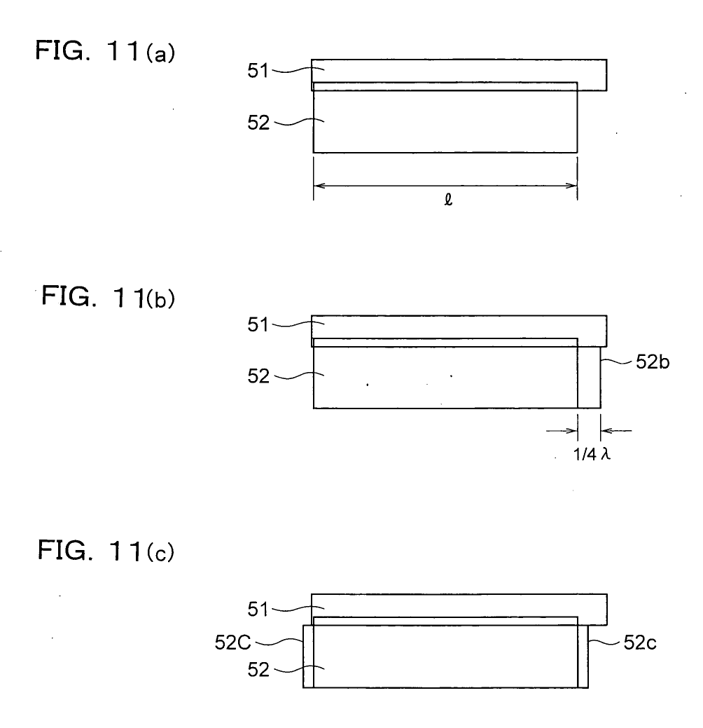

Also, as shown in FIG. 11(b), the end of the uniforming line 52 is extended by a distance of ¼λ.

Further, as shown in FIG. 11(c), an electromagnetic wave absorbing material with high dielectric loss (such as dummy load or water) is attached on the end of the uniforming line 52 to absorb the electromagnetic wave.

Also, for the purpose of preventing abnormal discharge (sparking) due to the increase of microwave output on the slot and of avoiding the crack of the dielectric substance in the uniforming line 52 due to local temperature increase, the slot plate 51c is made of a rigid metal plate of 3 to 5 mm in thickness as shown in FIG. 10, and the slot plate 51c is separated from the dielectric substance C made of a material such as quartz, alumina, etc. with atmospheric air space A interposed between them.

[How to Pass CVD Gas]

To pass CVD gas for film deposition in the microwave plasma CVD apparatus of the present invention, the following two methods are used: (1) gas down-flowing method, and (2) gas side-flowing method.

(Gas Down-flowing Method)

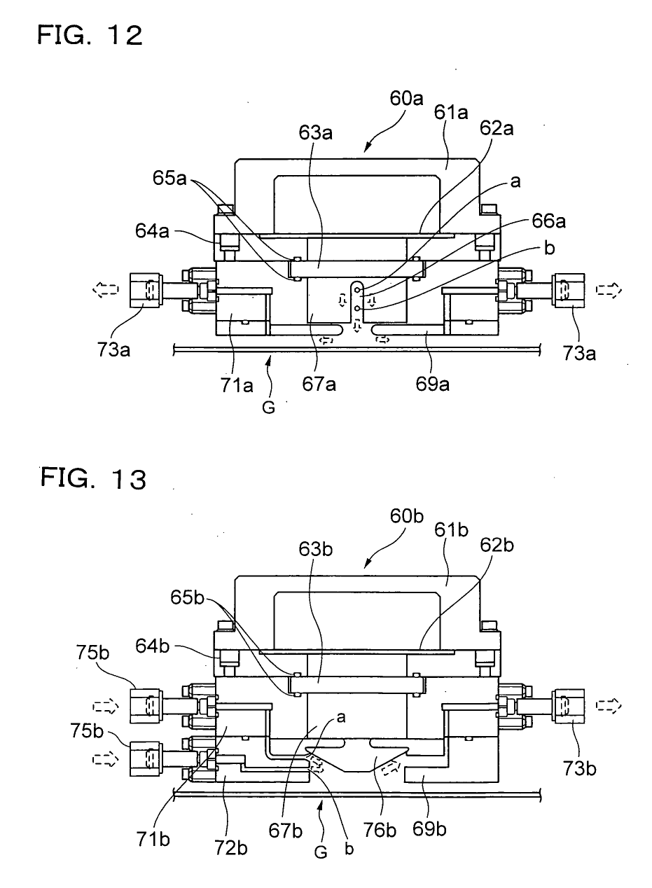

According to the gas down-flowing method, as shown in FIG. 12, the plasma head 60a comprises a waveguide 61a, a spacer 64a, a base flange 71a, a pair of exhaust ports 73a connected to the base flange 71a, and electrodes 69a mounted on the substrate G. A slit plate 62a is provided between the spacer 64a and lower end surface of the waveguide 61a. Also, a window 63a is arranged between the spacer 64a and upper end surface of the base flange 71a via a pair of O-rings 65a. Further, a spacer 67a is arranged under the window 63a, and a gas feeding nozzle 66a with a diluting gas exhaust port “a” and a raw gas exhaust port “b” is disposed in the spacer 67a (a uniforming line). Then, a film-forming gas comprising the diluting gas (e.g. Ar, He) and a raw material gas (e.g. SiH₄) is blown down toward film-forming surface of the substrate G through the exhaust ports “a” and “b” as shown by arrows.

As the result of the gas down-flowing, the film-forming gas flows to a portion with high plasma density, and this extensively improves film forming rate. This is also helpful to maintain homogeneousness of the film-forming gas, and the attachment of the remaining substances to the gas feeding nozzle can be prevented.

(Gas Side-flowing Method)

According to the gas side-flowing procedure, as shown in FIG. 13, a plasma head 60b comprises a waveguide 61b, a spacer 64b, a base flange 71b, a converting flange 72b, a pair of gas feeding ports 75b connected to the base flange 71b, an exhaust port 73b, and electrodes 69b mounted on the substrate G. A slit plate 62b is provided between the spacer 64b and lower end surface of the waveguide 61b. Also, a window 63b is provided between the spacer 64b and upper end surface of the base flange 71b via a pair of rollings 65b. A spacer 67b (a uniforming line) is arranged at lower end of the window 63b. Further, a head 76b in triangular shape is provided in a plasma chamber prepared between the lower end surface of this spacer 67b and the substrate G. Then, a diluting gas (e.g. Ar, He) is supplied through an exhaust port “a” of the gas feeding port 75b into the plasma chamber, and a raw material gas (such as SiH₄) is supplied through another injection port “b”. A film-forming gas is prepared by mixing these two types of gas, and the gas flows along the surface of the head 76b toward the substrate G as shown by arrows, and (side-flow) film forming is carried out. Then, the gas is exhausted to exhaust system through an exhaust port 73b. In this case, by changing the area of a flat surface 77b of the head 76b, film forming rate and film-forming condition can be adjusted.

By this side-flowing of the gas, homogeneity of the film-forming gas is improved, and exhaust operation can be promoted. Also, this makes it possible to predict the conditions on the film-forming surface and to facilitate the cleaning of the plasma head. Also, the width of the film formed on the substrate can be controlled by adjusting the shape of nozzle tip of the gas feeding port.

(Gas Shielding)

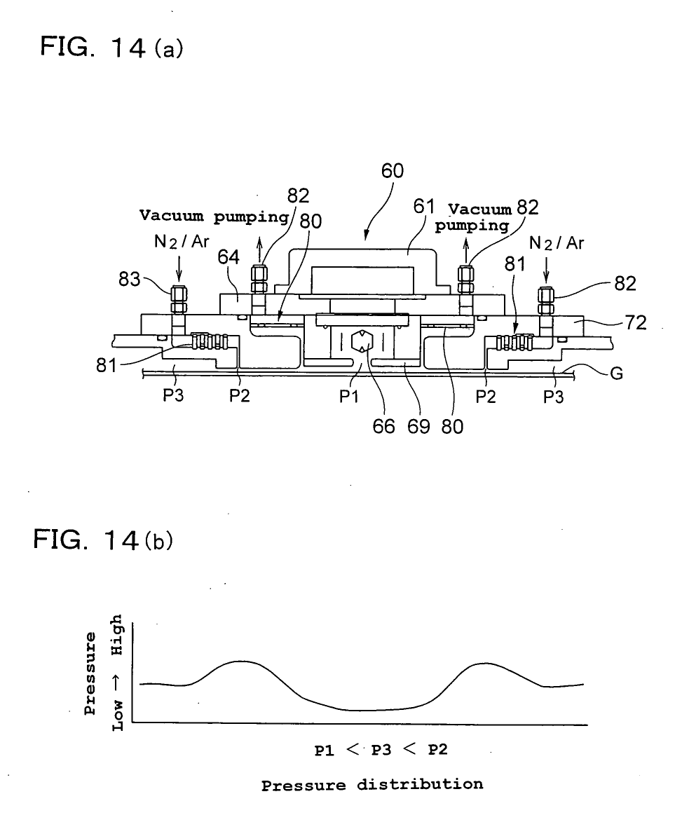

On the plasma head 60 of the microwave plasma CVD apparatus of the present invention, gas shielding is provided as shown in FIG. 14.

Specifically, as shown in FIG. 14(a), a vacuum exhaust pipe 82 is mounted on the spacer 64 arranged on the lower end of the waveguide 61 of the plasma head 60. also, shield gas feeding pipes 83 and 83 to feed N₂ and Ar gases etc. are connected to the converting flange 72 arranged on the lower end of the spacer 64 to form the plasma processing chamber with electrodes 69. Then, resistance plates 81 and 81 for providing unified feeding of the shield gas (N₂, Ar) toward downstream side are mounted. Further, resistance plates 80 and 80 for performing homogeneous exhaust of the film-forming gas supplied from the gas feeding nozzel 66 in the plasma processing chamber are arranged on the exhaust end of the film-forming gas.

Then, as shown in FIG. 14(b), it is designed in such manner that a pressure P₁ (pressure in the plasma processing chamber; e.g. pressure in the range between normal pressure and 1 Torr), P₂ (pressure near the resistance plate), and P₃ (pressure on the outermost periphery of the plasma head) are to be in the relation of P₁ <P₃ <P₂. Then, walls of pressure (pressure peaks) develop between the sites, and this prevents the leakage of the gas from the film-forming processing chamber, and perfect gas shielding can be provided.

1. A microwave plasma processing method in which a linear plasma is formed by using a microwave and an object to be processed is subjected to processing under atmospheric pressure or under a pressure near atmospheric pressure when the object to be processed is being moved while surface of the object to be processed is maintained at a horizontal position with respect to said linear plasma, wherein:
an H-plane slot antenna is provided in a plasma head, slots of said H-plane slot antenna being arranged alternately on both sides of a centerline of a waveguide with a pitch of λg/2 (λg: wavelength of the microwave within the waveguide), and a uniforming line being provided with a distance from said slots to an emission end of said plasma head being n·λg/2 (n: an integral number).

2. A microwave plasma processing method in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein:
an E-plane slot antenna is provided in a plasma head, slots of said E-plane slot antenna being arranged along a centerline of a waveguide with a pitch of λg (λg: wavelength of the microwave within the waveguide), and a uniforming line being provided with a distance from said slots to an emission end of said plasma head being n·λg/2(n: an integral number).

3. A microwave plasma processing method in which a linear plasma is formed by using a microwave and an object to be processed is subjected to processing under atmospheric pressure or under a pressure near atmospheric pressure when the object to be processed is being moved by while a surface of the object to be processed is maintained at a horizontal position with respect to said linear plasma, wherein:
a uniforming line being provided in a plasma head, said uniforming line is composed of a material with a high dielectric constant so as to reduce a standing wave in said plasma head.

4. A microwave plasma processing method in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein:
a uniforming line is provided in a plasma head, said uniforming line is composed of quartz, and an end portion thereof is extended by ¼λ (where λ represents free space wavelength within the quartz) so as to reduce a standing wave in said plasma head.

5. A microwave plasma processing method in which a linear plasma is formed by using a microwave and an object to be processed is subjected to processing under atmospheric pressure or under a pressure near atmospheric pressure when the object to be processed is being moved while the surface of the object to be processed is maintained at a horizontal position with respect to said linear plasma, wherein:
a uniforming line is provided in the plasma head, an electromagnetic wave absorbing member with a high dielectric loss being attached on an end of said uniforming line so as to reduce a standing wave in said plasma head.

6. A microwave plasma processing method in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein:
a film forming gas is supplied to the surface of the object to be processed by down-flowing through a film forming gas feeding nozzle provided in a plasma head.

7. A microwave plasma processing method in which a linear plasma is formed by using a microwave and for an object to be processed is subjected to processing under atmospheric pressure or under a pressure near atmospheric pressure when the object to be processed is being moved while a surface of the object to be processed is maintained at a horizontal position with respect to said linear plasma, wherein:
a film forming gas is supplied to the surface of the object to be processed by side-flowing through a film forming gas feeding nozzle provided in a plasma head.

8. A microwave plasma processing method in which a linear plasma is formed by using a microwave and an object to be processed is subjected to processing under atmospheric pressure or under a pressure near atmospheric pressure when the object to be processed is being moved while surface of the object to be processed is maintained at a horizontal position with respect to said linear plasma, wherein:
a shield gas feeding pipe is connected for feeding a shield gas into a plasma head, a buffer plate being provided for carrying out uniform feeding of the shield gas into a plasma processing chamber on a downstream side of the shield gas feeding pipe, and another buffer plate for carrying out homogeneous exhaust of the gas being provided on an exhaust side.

9. A microwave plasma processing method according to claim 8, wherein gas shielding is provided in such manner that pressure P₁ in said plasma processing chamber is set to a value lower than pressure P₃ on an outermost periphery of said plasma head, and the pressure P₃ is set to a value lower than the pressure P₂ near the another buffer plate for carrying out homogeneous gas exhaust, whereby leakage of the gas from said plasma head is prevented.

10. A microwave plasma processing method according to any one of claims 1 through 9, wherein said microwave plasma processing method is a microwave plasma CVD processing method.

11. A microwave plasma processing apparatus in which a linear plasma is formed by using a microwave and an object to be processed is subjected to processing under atmospheric pressure or under a pressure near atmospheric pressure when the object to be processed is being moved while a surface of the object to be processed is maintained at horizontal position with respect to said linear plasma, wherein;
an H-plane slot antenna is provided in a plasma head, slots of said H-plane slot antenna being arranged alternately on both sides of a centerline of a waveguide with a pitch of λg/2 (λg: wavelength of the microwave within the waveguide), and a uniforming line being provided with a distance from said slots to an emission end of said plasma head being n·λg/2 (n: an integral number).

12. A microwave plasma processing apparatus in which a linear plasma is formed by using microwave and an object to be processed is subjected to processing under atmospheric pressure or under a pressure near atmospheric pressure when the object to be processed is being moved while a surface of the object to be processed is maintained at a horizontal position with respect to said linear plasma, wherein;
an E-plane slot antenna is provided in a plasma head, slots of said E-plane slot antenna being arranged along a centerline of a waveguide with a pitch of λg (λg: wavelength of the microwave within the waveguide), and a uniforming line being provided with a distance from said slots to an emission end of said plasma head being n·λg/2 (n: an integral number).

13. A microwave plasma processing apparatus in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein:
a uniforming line being provided in a plasma head, said uniforming line is composed of a material with a high dielectric constant so as to reduce a standing wave in said plasma head.

14. A microwave plasma processing apparatus in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein:
a uniforming line is provided in a plasma head, said uniforming line is composed of quartz, an end portion thereof being extended by ¼λ (λ: free space wavelength of the microwave within the quartz) sp as to reduce a standing wave in said plasma head.

15. A microwave plasma processing apparatus in which a linear plasma is formed by using a microwave and for processing an object to be processed is subjected to processing under atmospheric pressure or under a pressure near atmospheric pressure when the object to be processed is being moved while a surface of the object to be processed is maintained at a horizontal position with respect to said linear plasma, wherein:
a uniforming line is provided in a plasma head, an electromagnetic wave absorbing member with a high dielectric loss being attached on an end of said uniforming line so as to reduce a standing wave in said plasma head.

16. A microwave plasma processing apparatus in which a linear plasma is formed by using a microwave and for processing an object to be processed is subjected to processing under atmospheric pressure or under a pressure near atmospheric pressure when the object to be processed is being moved while surface of the object to be processed is maintained at a horizontal position with respect to said linear plasma, wherein:
a film forming gas is supplied to the surface of the object to be processed by down-flowing through a film forming gas feeding nozzle provided in the plasma head.

17. A microwave plasma processing apparatus in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein:
a film forming gas is supplied to the surface of said object to be processed by side-flowing through a film forming gas feeding nozzle provided in the plasma head.

18. A microwave plasma processing apparatus in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein:
a shield gas feeding pipe is connected for feeding a shield gas into a plasma head, a buffer plate being provided for carrying out uniform feeding of the shield gas into a plasma processing chamber on a downstream side of the shield gas feeding pipe, and another buffer plate for carrying out homogeneous exhaust of the gas being provided on an exhaust side.

19. A microwave plasma processing apparatus according to claim 18, wherein gas shielding is provided in such manner that pressure P₁ in said plasma processing chamber is set to a value lower than pressure P₃ on an outermost periphery of said plasma head, and the pressure P₃ is set to a value lower than the pressure P₂ near the another buffer plate for carrying out homogeneous gas exhaust, whereby leakage of the gas from said plasma head is prevented.

20. A microwave plasma processing apparatus according to any one of claims 11 through 19, wherein said microwave plasma processing method is a microwave plasma CVD processing method.

21. A plasma head of a microwave plasma processing apparatus in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein;
an H-plane slot antenna is provided in a plasma head, slots of said H-plane slot antenna being arranged alternately on both sides of a centerline of a waveguide with a pitch of λg/2 (λg: wavelength of the microwave within the waveguide), and a uniforming line being provided with a distance from said slots to an emission end of said plasma head being n·λg/2(n: an integral number).

22. A plasma head of a microwave plasma processing apparatus in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein;
an E-plane slot antenna is provided in a plasma head, slots of said E-plane slot antenna being arranged along a centerline of a waveguide with a pitch of λg (λg: wavelength of the microwave within the waveguide), and a uniforming line being provided with a distance from said slots to an emission end of said plasma head being n·λg/2(n: an integral number).

23. A plasma head of a microwave plasma processing apparatus in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein;
a uniforming line being provided in a plasma head, said uniforming line is composed of a material with a high dielectric constant so as to reduce a standing wave in said plasma head.

24. A plasma head of a microwave plasma processing apparatus in which a linear plasma is formed by using a microwave and an object to be processed is subjected to processing under atmospheric pressure or under a pressure near the atmospheric pressure when the object to be processed is being moved while a surface of the object to be processed is maintained at a horizontal position with respect to said linear plasma, wherein;
a uniforming line is provided in a plasma head, said uniforming line is composed of quartz, an end portion thereof being extended by ¼λ (λ: free space wavelength of the microwave within the quartz) so as to reduce a standing wave in said plasma head.

25. A plasma head of a microwave plasma processing apparatus in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein;
a uniforming line is provided in a plasma head, an electromagnetic wave absorbing member with a high dielectric loss being attached on an end of said uniforming line so as to reduce a standing wave in said plasma head.

26. A plasma head of a microwave plasma processing apparatus in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein;
a film forming gas is supplied to the surface of the object to be processed by down-flowing through a film forming gas feeding nozzle provided in a plasma head.

27. A plasma head of a microwave plasma processing apparatus in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein;
a film forming gas is supplied to the surface of the object to be processed by side-flowing through a film forming gas feeding nozzle provided in a plasma head.

28. A plasma head of a microwave plasma processing apparatus in which a linear plasma is formed by using a microwave and an object to be processed is subjected to processing under atmospheric pressure or under a pressure near atmospheric pressure when the object to be processed is being moved while a surface of the object to be processed is maintained at a horizontal position with respect to said linear plasma, wherein;
a shield gas feeding pipe is connected for feeding a shield gas into a plasma head, a buffer plate being provided for carrying out homogeneous feeding of the shield gas into a plasma processing chamber on a downstream side of the shield gas feeding pipe, and a another buffer plate for carrying out homogeneous exhaust of the gas is provided on an exhaust side.

29. A plasma head of a microwave plasma processing apparatus according to claim 28, wherein gas shielding is provided in such manner that pressure P₁ in said plasma processing chamber is set to a value lower than pressure P₃ on an outermost periphery of said plasma head, and the pressure P₃ is set to a value lower than the pressure P₂ near the another buffer plate for carrying out uniform gas exhaust, whereby the leakage of the gas from said plasma head is prevented.

30. A plasma head of a microwave plasma processing apparatus according to any one of claims 21 through 29, wherein said microwave plasma processing apparatus is a microwave plasma CVD processing apparatus.

31. A method for manufacturing FPD or a semiconductor device, characterized in that a film is formed by use of the microwave plasma processing method according to any one of claims 1 through 10.
